(19) United States
(12) Patent Application Publication
(10) Pub. No.: US 2001/0032996 A1
(43) Pub. Date: Oct. 25, 2001

(54) Nonvolatile semiconductor memory device

(76) Inventor: Tatsuro Inoue, Tokyo (JP)

Correspondence Address: OSTROLENK FABER GERB & SOFFEN, 1180 AVENUE OF THE AMERICAS, NEW YORK, NY, 100368403

(21) Appl. No.: 09/838,030

(22) Filed: Apr. 19, 2001

(30) Foreign Application Priority Data
Apr. 25, 2000 (JP) 124843/2000

(51) Int. Cl. H01L 29/76; H01L 29/94; H01L 29/788; H01L 31/062

(52) U.S. Cl. 257/314; 257/315; 257/316; 257/317; 257/390

(57) ABSTRACT

A nonvolatile semiconductor memory device includes element isolation regions composed of a plurality of trenched groove parts formed in a semiconductor substrate, an oxide film formed among a plurality of the element isolation regions on the semiconductor substrate, a first floating gate formed on the oxide film, side wall parts formed on the oxide film from the side wall parts of the first floating gate to the end rim parts of the element isolation regions, a second floating gate formed at least on the first floating gate, and a control gate formed on the second floating gate through a gate insulation film.

### BACKGROUND OF THE INVENTION

1. Field of the Invention

The present invention relates to a nonvolatile semiconductor memory device, and more particularly to a structure of a flash memory which allows variation of threshold value of a floating gate to be suppressed and reduction of data storage reliability to be prevented.

2. Description of the Prior Art

A representative structure of a flash memory widely known conventionally as a practical example of a nonvolatile semiconductor memory device is illustrated in FIG. 2.

That is, in the conventional nonvolatile semiconductor memory device, as illustrated in FIG. 2, after trenched groove parts 11 are formed in a semiconductor substrate 10, the trenched groove parts 11 are filled with a proper insulation film 12 to form element isolation regions 20 and then a tunnel oxide film 13 is properly formed and floating gates 14 are formed by patterning while being well conformed. When such processes are carried out, in case of removing the tunnel oxide film formed on the substrate by wet etching, since the tunnel oxide film 13 in the channel region end parts 21 is affected by the groove isolation regions 20, the tunnel oxide film 13 in those parts is made thin and recessed parts 22, called as depots, are formed in the connection parts of the channel region end parts 21 and the end parts of the trenched groove parts 11 and also due to that, the thickness of the tunnel oxide film 13 in the foregoing parts is made thin in many cases.

That is, in the above described conventional example, since dents 22 are formed in the tunnel oxide film 13 in the channel end parts 21, which are end parts of the groove isolation regions 20, the tunnel oxide film 13 is made thin in these parts and it results in variation of the threshold values and easy occurrence of data elimination from the floating gates to the substrate.

Consequently, in the foregoing nonvolatile semiconductor memory device containing such defects, the electric charge accumulated in the foregoing floating gates 14 escapes to the substrate 10 from the recessed parts 22 of the foregoing tunnel oxide film 13, so that the threshold values of the foregoing floating gates 14 are lowered and the threshold values of the respective floating gates in each nonvolatile semiconductor memory device become uneven and as a result, the nonvolatile semiconductor memory device holds a problem that the reliability of data storage is worsened.

One of the causes is supposed to be attributed to the fact that the foregoing floating gates 14 and the end parts of the foregoing trenched groove parts 11 are brought into contact with each other since the groove isolation regions 20 are formed in the substrate 10 and then the floating gates are patterned while being conformed, as described above.

Incidentally, in FIG. 2, the reference numeral 15 denotes an insulation film of an ONO film or the like and the reference numeral 16 denotes a control gate.

Further, regarding the nonvolatile semiconductor memory device, for example, Japanese Patent Laid-Open No. 11-26731 is known and although the specification discloses a technique which prevents the film thickness of the trenched groove parts from becoming thin while using mainly NAND type EEPROMs in a nonvolatile semiconductor memory device comprising nonvolatile semiconductor memory element array, there has been disclosed no nonvolatile semiconductor memory device in which the end parts of the trenched groove parts and the end parts of the floating gates are parted from each other as invented in the present invention.

On the other hand, although Japanese Patent Laid-Open No. 11-26730 discloses a NAND type nonvolatile semiconductor memory device having a constitution in which side wall-like floating gates are formed in the side walls of an element isolation region projected on a substrate and a control gate is formed as to cover the floating gates in order to increase the coupling ratio between the control gate and floating gate, there has been disclosed no nonvolatile semiconductor memory device in which the end parts of the trenched groove parts and the end parts of the floating gates are parted from each other as proposed by the present invention.

Also, although Japanese Patent Laid-Open No. 11-317464 discloses a nonvolatile semiconductor memory device having the electrode constitution in which a charge accumulation film and a control electrode are layered in order to make the capacity coupling ratio of a control gate and a floating gate high and comprising side wall parts and conductive layers for shielding in the side faces facing to the source and drain regions of the foregoing electrode constitution, the specification proposes only the constitution where the floating gates and the element isolation regions are connected closely to each other as same in a conventional one, and therefore, there is no description of a nonvolatile semiconductor memory device in which the end parts of the foregoing trenched groove parts and the end parts of the foregoing floating gates are separated from each other.

Hence, an object of the present invention is to provide a structure of a nonvolatile semiconductor memory device in which the variation of the threshold values of the floating gates is suppressed, the reduction of the data storage reliability is prevented and at the same time the capacity coupling ratio is kept not lower than that of a conventional cell by solving the disadvantages of the above described conventional technique, and to provide a method for fabricating the same.

### BRIEF SUMMARY OF THE INVENTION

Objects of the Invention

An object of the present invention is to provide a structure of a nonvolatile semiconductor memory device in which the variation of the threshold values of the floating gates is suppressed, the reduction of the data storage reliability is prevented and at the same time the capacity coupling ratio is kept not lower than that of a conventional cell.

Summary of the Invention

A nonvolatile semiconductor memory device of the present invention comprises element isolation regions comprising a plurality of trenched groove parts formed in a semiconductor substrate, an oxide film formed on the semiconductor substrate in gaps among a plurality of the element isolation regions, first floating gates formed on the oxide film, side wall parts formed on the oxide film from the side wall parts of the first floating gate to the rim parts of the element isolation regions, second floating gates formed at least on the first floating gates, and control gates formed on the second floating gates through a gate insulation film.

### BRIEF DESCRIPTION OF THE DRAWINGS

The above-mentioned and other objects, features and advantages of the present invention will become more apparent by reference to the following detailed description of the invention taken in conjunction with the accompanying drawings, wherein:

FIG. 1 is a cross-sectional view showing the constitution of the nonvolatile semiconductor memory device of the present invention;

FIG. 2 is a cross-sectional view showing one constitution example of a conventional nonvolatile semiconductor memory device;

FIG. 3A to FIG. 3C are figures illustrating procedure of the fabrication method of a nonvolatile semiconductor memory device of the present invention;

FIG. 4A to FIG. 4C are figures illustrating other procedure of the fabrication method of a nonvolatile semiconductor memory device of the present invention; and

FIG. 5 is a figure showing one practical example of an array structure in the case where a nonvolatile semiconductor memory device of the present invention is arranged in NOR arrangement.

### DETAILED DESCRIPTION OF THE INVENTION

Hereinafter, the constitution of one practical example of a nonvolatile semiconductor memory device of the present invention will be described in detail with reference to the drawings.

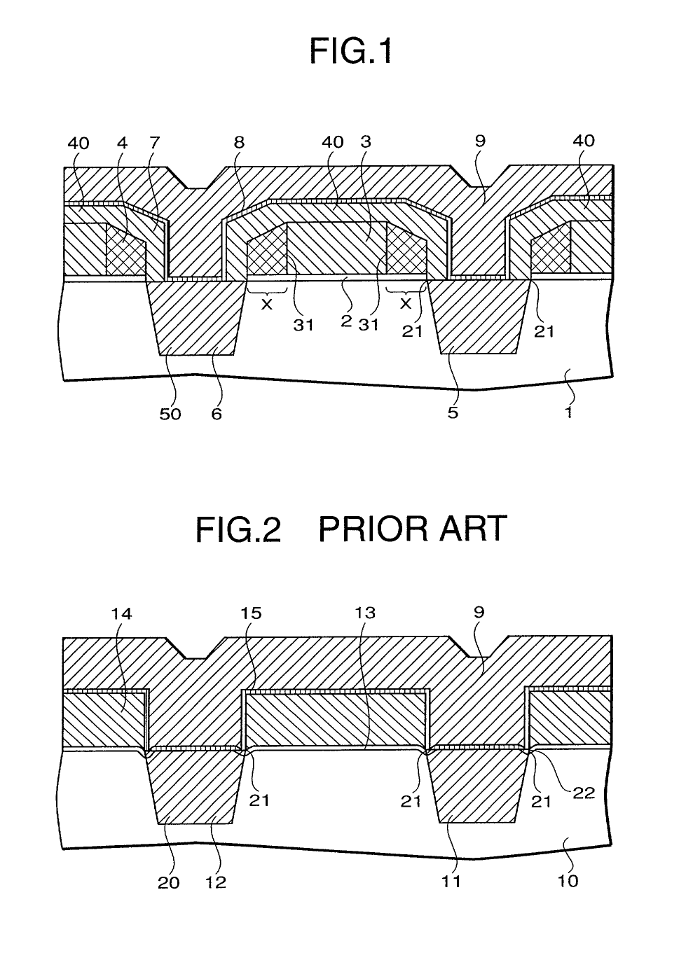

FIG. 1 is a cross-sectional view showing the constitution of one practical example of a nonvolatile semiconductor memory device of the present invention, and in this drawing, the nonvolatile semiconductor memory device is shown which is an NOR type nonvolatile semiconductor memory device in which a plurality of nonvolatile semiconductor memory element cells 40 are arranged in array state in a substrate 1 through element isolation regions 50 composed of trenched groove parts 5. Each of the cells 40 comprises a first floating gate 3 formed on the substrate 1 through an oxide film 2 and whose side wall end parts 31 are formed while being isolated from the rim parts 21 of the relevant trench grove parts 5.

The nonvolatile semiconductor memory device of the present invention is preferably a flash memory.

Further, the nonvolatile semiconductor memory device of the present invention is preferably an NOR type flash memory.

Also, in the nonvolatile semiconductor memory device of the present invention, side walls 4 are preferably formed in the side wall end parts 31 of the first floating gate 3.

Moreover, in the present invention, the side walls 4 are required to be formed as to fill the gap parts X between the side wall end parts 31 of the first floating gate 3 and the rim parts 21 of the relevant trenched groove parts 5.

The thickness of the side walls 4 is not specifically limited and properly selected to be with in a range as to achieve the above described effect.

On the other hand, in the present invention, it is preferable to forma second floating gate 7 joined to the upper part surface of the first floating gate 3.

The second floating gate 7 in the present invention is required to be electrically brought into contact with at least a part of the first floating gate 3 and further, in order to obtain a high coupling capacity ratio, the surface area of the second floating gate is more preferable to be wider and as shown in FIG. 1, the second floating gate 7 is preferably provided to entirely coat the first floating gate 3 and the side wall parts 4.

Incidentally, although the source and drain regions are not illustrated in FIG. 1, it is no need to say that the source and drain regions are formed in the front surface and the rear surface of the substrate.

In other words, in the present invention, the surface area of the second floating gate 7 is preferably wider than the surface area of the first floating gate 3.

Further, in the present invention, the trenched groove parts 5 are preferably formed by self-alignment in relation to the side walls 4 and also a most part of the surface of the second floating gate 7 in the present invention is preferably coated with a control gate 9 with an insulation film 8 interposed therebetween.

By the present invention, the data storage reliability of a flash memory cell can be kept high regardless of the shape of the tunnel film 2 of the channel end parts 31 by forming the trenched groove parts 5 while keeping them from the channel end parts 31.

Further, a high capacity ratio can be obtained by making the floating gates 3, 7 be double layers.

Consequently, in the present invention, since the trenched groove parts 5 formed in self-alignment manner in the side walls 4 formed in the side walls 31 of the floating gate 3 are isolated from the channel end parts 21, the electric charge leakage can be prevented and further, the floating gates 3, 7 are formed to be the double layer structure, the coupling capacity is not lowered as compared with a conventional nonvolatile semiconductor memory device to result in data storage reliability.

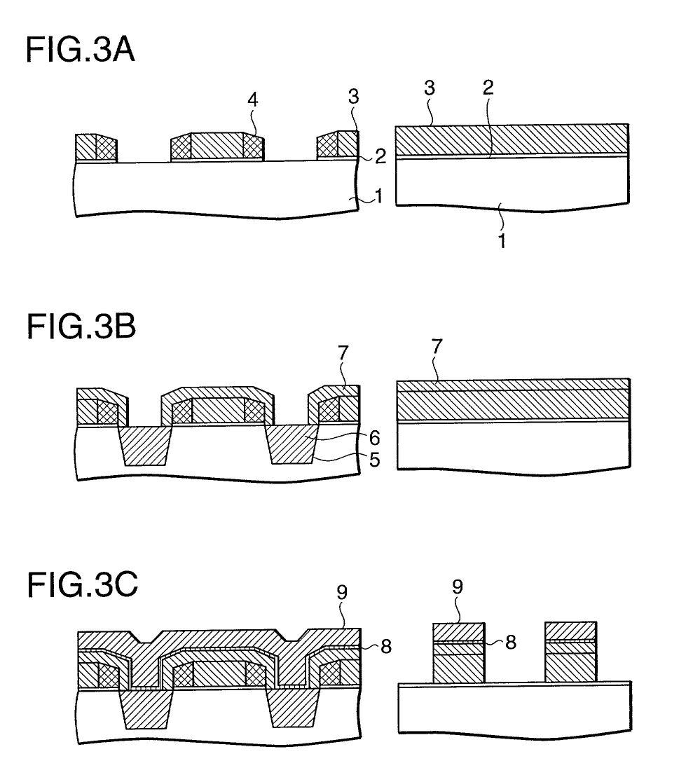

Hereinafter, the detailed fabrication process of the nonvolatile semiconductor memory device of the present invention will be described with reference to FIGS. 3.

A first gate insulation film 2 of 10 nm thickness is formed on the surface of, for example, a P-type semiconductor substrate 1.

Next, a first floating gate 3 of polysilicon, for example, in 150 nm thickness is patterned in a prescribed region.

Next, a nitride film of, for example, 100 nm thickness is formed and etched back to leave side walls 4 in the side walls of the foregoing first floating gate 3. (see FIG. 3A) Next, trenched groove parts 5 of 300 nm depth are formed in self-alignment manner in the side walls 4 in the surface of the semiconductor substrate 1 and then an insulation film 6 of, for example, TEOSNSG is buried in the trenched groove parts by etching back process.

Next, a second floating gate 7 of polysilicon, for example, in 50 nm thickness is patterned as to cover the first foregoing floating gate 3 and the side walls 4. (see FIG. 3B) Next, a second gate insulation film 8, for example, an ONO (SiO₂/Si₃N₄/O₂) film, is formed by a CVD method.

Next, a control gate 9 of polysilicon in, for example, 300 nm thickness is formed and then patterned.

At that time, the foregoing second gate insulation film 8 as a lower layer, the second floating gate 7, and the first floating gate 3 are patterned in self-alignment manner to the control gate 9 to form a gate electrode of a memory cell. (see FIG. 3C) Although being not illustrated, thereafter, source and drain regions are formed, an interlayer insulation film is formed, contacts are formed, and metal wiring is carried out to fabricate a transistor.

Further, in the foregoing nonvolatile semiconductor memory device, the method employed for increasing the threshold voltage is the way that electrons are injected to the first floating gate 3 from some of electric current flowing between the source and the drain based on hot electron manner at the time of data write.

Further, at the time of data elimination, the method employed for lowering the threshold voltage is the way of causing depletion of electrons to the substrate 1 from the first floating gate 3 based on the F-N tunneling manner.

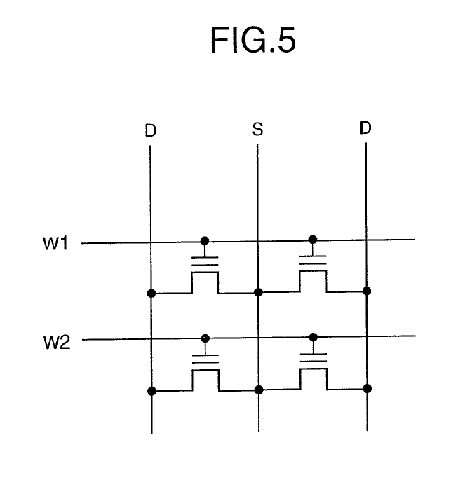

The array method in the present invention requires NOR type as shown in FIGS. 5 and the cell surface area as same as that of a conventional flash memory can be obtained.

In the foregoing nonvolatile semiconductor memory device of the present invention, being different from the case of a cell employing a conventional STI (shallow trench isolation) in which the threshold voltage variation and the inferior data storage reliability are problems attributed to the dents formed in the end parts of STI, the end parts 21 of the element isolation regions 5 are isolated from the first floating gate 3 owing to the side walls 4 formed in the side walls 31 of the first floating gate 3, so that such problems of the threshold voltage variation and the inferior data storage reliability can be solved and moreover, owing to the existence of the second floating gate, the capacity ratio as high as that of a conventional cell can be obtained.

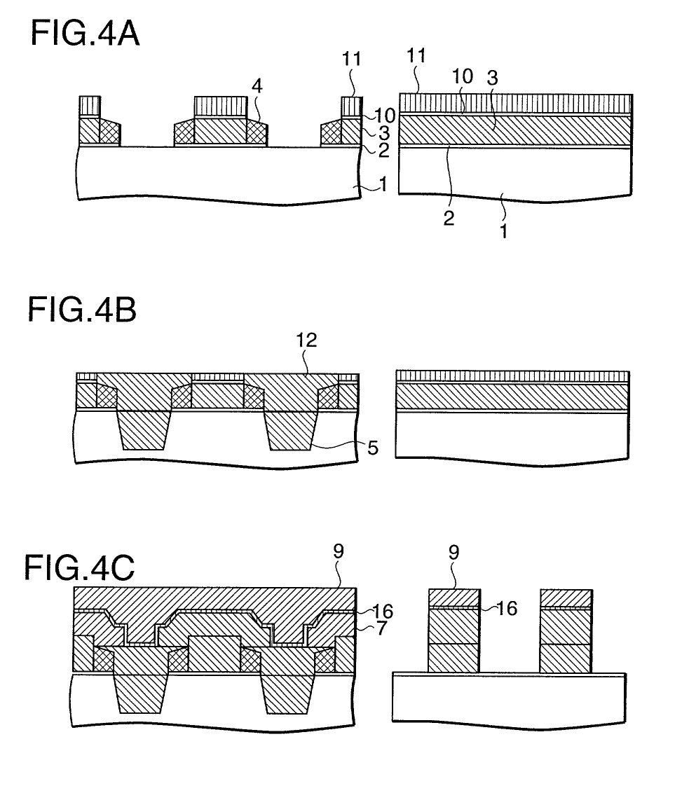

Next, another specific fabrication process of the nonvolatile semiconductor memory device of the present invention will be described with reference to FIGS. 4 A first gate insulation film 2 of 10 nm thickness is formed on the surface of, for example, a P-type semiconductor substrate 1.

Next, a polysilicon layer 3 of, for example, 150 nm thickness to be a first floating gate thereafter and an oxide film 10 of, for example, 50 nm thickness, and a nitride film 11 of, for example, 150 nm thickness are layered by a CVD method.

Next, the nitride film 11, the oxide film 10, and the polysilicon layer 3 are patterned at prescribed positions.

Next, an oxide film of, for example, 100 nm thickness is formed by a CVD method and etched back to form side walls 4 in side walls of the first floating gate 3. (see FIG. 4A) Next, trenched groove parts 5 of 300 nm thickness are formed in self-alignment manner with respect to the side wall 4 on the surface of the semiconductor substrate 1.

Next, a TEOSBPSG film 12 of, for example, 500 nm thickness is formed by a CVD method and then polished by a CMP method until the surface of the foregoing nitride film 11 comes up. (see FIG. 4B)

Next, the foregoing nitride film 11 is removed by hot phosphoric acid or the like and wet etching with a buffered hydrofluoric acid is carried out until the surface of the first floating gate 3 is exposed.

Next, a second floating gate 7 of polysilicon in, for example, 50 nm thickness is patterned as to cover the first floating gate 3.

Next, a control gate 9 of polysilicon in, for example, 300 nm thickness is formed and patterned.

At that time, the foregoing second gate insulation film 16 as a lower layer, the second floating gate 7, and the first floating gate 3 are patterned in self-alignment manner to the control gate 9 to form a gate electrode of a memory cell. (see FIG. 4C)

Although being not illustrated, thereafter, source and drain regions are formed, an interlayer insulation film is formed, contacts are formed, and metal wiring is carried out to fabricate a transistor.

Since the nonvolatile semiconductor memory device of the present invention employed the above described method employed, electric charge leakage is prevented owing to that the trenched groove parts 5 formed in self-alignment manner on the side walls 4 formed in the side walls 31 of the floating gate 3 are parted from the channel end parts 21 and further the coupling capacity is not lowered as compared with that in a conventional nonvolatile semiconductor memory device owing to the double layer structure of the floating gates 3, 7 and consequently the data storage reliability is improved.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A nonvolatile semiconductor memory device comprising:
element isolation regions composed of a plurality of trenched groove parts formed in a semiconductor substrate;
an oxide film formed among a plurality of said element isolation regions on said semiconductor substrate;
a first floating gate formed on said oxide film, side wall parts formed on said oxide film from said side wall parts of said first floating gate to the end rim parts of said element isolation regions;
a second floating gate formed at least on said first floating gate; and
a control gate formed on said second floating gate through a gate insulation film.

2. The nonvolatile semiconductor memory device according to claim 1, wherein the surface area of said second floating gate is wider than the surface area of said first floating gate.

3. The nonvolatile semiconductor memory device according to claim 1, wherein said element isolation regions are formed in self-alignment manner in relation to said side wall parts.

4. The nonvolatile semiconductor memory device according to claim 1, wherein said second floating gate covers said side wall parts and reaches parts of said element isolation regions.

5. The nonvolatile semiconductor memory device according to claim 1, wherein said nonvolatile semiconductor memory device is a NOR type flash memory.

6. The nonvolatile semiconductor memory device according to claim 1, wherein said side wall parts is made of an insulator.
